(19) United States
(12) Patent Application Publication
(10) Pub. No.: US 2012/0222721 A1
(43) Pub. Date: Sep. 6, 2012

(54) PHOTOVOLTAIC MODULE PACKAGE AND FABRICATION METHOD

(75) Inventors: Thomas Bert Gorczyca, Schenectady, NY (US); Charles Steven Korman, Niskayuna, NY (US); Scott Smith, Niskayuna, NY (US)

(73) Assignee: GENERAL ELECTRIC COMPANY, Schenectady, NY (US)

(21) Appl. No.: 13/038,811

(22) Filed: Mar. 2, 2011

(51) Int. Cl. H01L 31/052; H01L 31/0232

(52) U.S. Cl. 136/246; 438/68; 257/E31.127

(57) ABSTRACT

A photovoltaic module package and fabrication method. The module includes photovoltaic cells, a dielectric material, and metallized material. Each photovoltaic cells includes a substrate material having a sun side and a backside, first doped regions interdigitated with second doped regions, both doped regions being located on the backside, and one being positively doped and the being negatively doped, and electrical contacts on each of the first and second doped regions. The dielectric material is adhered to the backside of the substrate material. Vias are formed through the dielectric material, extending to at least a portion of the electrical contacts. The metallized material extends from the electrical contacts through the vias and are patterned on a backside of the dielectric material. The metallized material is formed of a material that is both electrically and thermally conductive.

### FIELD

The invention relates to photovoltaic module packaging, and more particularly to packaging for photovoltaic cell array modules having backside contacts.

### BACKGROUND

Generally, photovoltaic devices convert radiation, such as solar, incandescent, or fluorescent radiation, into electrical energy. Sunlight is the typical source of radiation for most devices. The conversion to electrical energy may be achieved by the well-known “photovoltaic effect”. According to this phenomenon, radiation striking a photovoltaic device can enter the absorber region of the device, generating pairs of electrons and holes, which are sometimes collectively referred to as photo-generated charge carriers. Generally, the electrons and holes diffuse in the absorber region, and are collected at the contacts.

The increasing interest in solar cells as a reliable form of clean, renewable energy has prompted great efforts in increasing the performance of the cells. Typically, one way to improve cell performance is to improve the photoelectric conversion efficiency of the device. Conversion efficiency is usually measured as the amount of electrical current generated by the device, as a proportion of the light energy that falls on its active surface area. Typical photovoltaic devices exhibit a conversion efficiency on a module level of about 20% or less. Small increases in photoelectric conversion efficiency, e.g., 1% or less, can represent very significant advances in photovoltaic technology.

To improve photovoltaic conversion efficiency, various conditions that contribute to the reduction in cell efficiency can be minimized. For example, shadowing effects, which can limit the device performance, should be considered, especially for cells which may be used for generating electricity in concentrated sunlight applications. Shadowing effects generally refer to the shadowing created by the presence of the relatively large bus bars on the front surface of the photovoltaic device. The bus bars generally serve as one of the conducting electrodes of the device. Disadvantageously, by placing bus bars on the front surface of the device, a significant proportion of incident light rays can be blocked at the contact areas. The light blockage is generally referred to as “shading” or “shadowing.” Shadowing prevents the areas of the underlying active materials from receiving incident radiation, thereby reducing the generation of charge carriers. Obviously, a reduction in charge carriers can reduce the efficiency of the photovoltaic device. Moreover, having contacts on the front side of the device can increase the complexity of manufacturing modules comprising many photovoltaic devices.

With some of these concerns in mind, improved methods of fabricating and packaging photovoltaic devices would be welcome in the art. The methods would desirably allow for the use of all-back contacts, and further, result in the production of high efficiency photovoltaic devices.

### SUMMARY

An embodiment of the invention includes a photovoltaic module. The module includes an array of photovoltaic cells, each photovoltaic cell comprising a substrate material having a sun side and a backside, a first plurality of doped regions interdigitated with a second plurality of doped regions, wherein both of the doped regions are located on the backside and wherein one of the plurality of doped regions is positively doped and the other plurality of doped regions is negatively doped, and electrical contacts on each of the first and second plurality of doped regions. The module further includes a dielectric material adhered through a first adhesive layer to the backside of the substrate material, wherein vias are formed through the dielectric material and the first adhesive layer and extending to at least a portion of the electrical contacts. The module also includes metallized material extending from at least a portion of the electrical contacts through the vias and being patterned on a backside of the dielectric material, the metallized material being formed of a material that is both electrically and thermally conductive.

An embodiment of the invention includes a method for fabricating a photovoltaic module by securing a backside contact photovoltaic cell array as an integral piece onto a first side of a dielectric material through an adhesive layer, forming at least two vias through the adhesive layer and the dielectric material to each cell of the photovoltaic cell array, patterning a metal layer on selected portions of a second side of the dielectric material and in the vias so that the photovoltaic cells are serially connected together, said metal layer also creating a thermal pathway, and cutting the integral piece into separate photovoltaic cells, thereby electrically isolating the photovoltaic cells.

These and other features, aspects and advantages of the present invention may be further understood and/or illustrated when the following detailed description is considered along with the attached drawings.

### DESCRIPTION OF THE DRAWINGS

FIG. 1 is a sectional side view of a completed photovoltaic module packaged according to one embodiment.

FIGS. 2A-2C are sectional side views of a photovoltaic module in different stages of a fabrication sequence according to one embodiment.

FIG. 3 is a top view of an incomplete photovoltaic module according to one embodiment.

FIG. 4 is a top view of an electrically connected photovoltaic module according to one embodiment.

FIG. 5 is a top view of an electrically connected photovoltaic module showing a metallization layer and multiple vias according to one embodiment.

FIG. 6 is a partial top view of completed photovoltaic module having trench contacts to the silicon junction areas according to one embodiment.

FIG. 7 is a partial top view of completed photovoltaic module having point contacts to the silicon junction areas according to one embodiment.

FIG. 8 is a graphical depiction of the performance of a two completed photovoltaic modules prepared in accordance with embodiments.

FIG. 9 illustrates sectional side views of a photovoltaic module in different stages of a fabrication sequence according to one embodiment.

FIG. 10 depicts processing steps for fabricating a photovoltaic module according to one embodiment.

### DETAILED DESCRIPTION

The present specification provides certain definitions and methods to better define the embodiments and aspects of the invention and to guide those of ordinary skill in the art in the practice of its fabrication. Provision, or lack of the provision, of a definition for a particular term or phrase is not meant to imply any particular importance, or lack thereof; rather, and unless otherwise noted, terms are to be understood according to conventional usage by those of ordinary skill in the relevant art.

Unless defined otherwise, technical and scientific terms used herein have the same meaning as is commonly understood by one of skill in the art to which this invention belongs. The terms “first”, “second”, and the like, as used herein do not denote any order, quantity, or importance, but rather are used to distinguish one element from another. Also, the terms “a” and “an” do not denote a limitation of quantity, but rather denote the presence of at least one of the referenced item, and the terms “front”, “back”, “bottom”, and/or “top”, unless otherwise noted, are merely used for convenience of description, and are not limited to any one position or spatial orientation. If ranges are disclosed, the endpoints of all ranges directed to the same component or property are inclusive and independently combinable (e.g., ranges of “up to about μwt. %, or, more specifically, about 5 wt. % to about 20 wt. %,” is inclusive of the endpoints and all intermediate values of the ranges of “about 5 wt. % to about 25 wt. %,” etc.).

The modifier “about” used in connection with a quantity is inclusive of the stated value and has the meaning dictated by the context (e.g., includes the degree of error associated with measurement of the particular quantity). Reference throughout the specification to “one embodiment”, “another embodiment”, “an embodiment”, and so forth, means that a particular element (e.g., feature, structure, and/or characteristic) described in connection with the embodiment is included in at least one embodiment described herein, and may or may not be present in other embodiments. In addition, it is to be understood that the described inventive features may be combined in any suitable manner in the various embodiments.

The present methods utilize Chip on Flex (COF) and/or High Density Integration (HDI) techniques to package a high voltage, photovoltaic module. In some embodiments, combinations of HDI and/or COF fabrication processes may be utilized. Such techniques are advantageous in that individual cells of a multi-cell PV module can be manufactured in close proximity to minimize irradiance loss between cells, a flexible dielectric layer protects the sensitive backside contact area of the device, provides mechanical reinforcement to thin mounted substrates and allows slight bending of the devices, and a metal layer reduces current crowding, provides heat spreading and allows serial connection. Having cells in close proximity is especially advantageous in solar concentrating systems as it enables collection of a greater amount of the concentrated irradiance. Serial connection of cells allows higher voltage operation with less current, minimizing I²R losses. The serial connection assists in current flow across the device junctions, and can be used as a heat spreading layer to assist with heat removal when a heat sink is added. Although some of the fabrication processes described have been utilized to provide various other electronic modules, such as circuit chip packages, such fabrication processes have not been used to provide modules comprising multiple photovoltaic cells, at least in part because low cost fabrication methods for applying devices onto flex void free and subsequently processing them to form vias and patterned metal on the flex have not been available.

HDI, in this context, comprises high density multichip module manufacturing processes, which can include one or more adaptive lithography processes wherein a substrate of a particular material, such as a ceramic substrate, may be formed with one or more cavities suitable to receive one or more components. HDI fabrication processes have been developed by General Electric Company, and numerous methods of fabrication in accordance with one or more embodiments of HDI are disclosed in the following: U.S. Pat. No. 4,835,704, entitled “Adaptive Lithography System to Provide High Density Interconnect”, by Eichelberger et al., issued May 30, 1989, and assigned to General Electric Company; U.S. Pat. No. 5,357,403, entitled “Adaptive Lithography in a High Density Interconnect Structure Whose Signal Layers Have Fixed Patterns”, by Haller et al., issued Oct. 18, 1994, and assigned to General Electric Company; U.S. Pat. No. 5,449,427, entitled “Processing Low Dielectric Constant Materials for High Speed Electronics”, by Wojnarowski et al., issued Sep. 12, 1995, and assigned to General Electric Company; and U.S. Pat. No. 6,242,882 entitled “Circuit Chip Package and Fabrication Method” by Fillion et al., issued Jun. 5, 2001 and assigned to the General Electric Company. Each of these references is hereby incorporated by reference herein in its entirety for any and all purposes.

More particularly, in the present method, at least two photovoltaic cells, which may typically be provided on, e.g., a silicon substrate, are secured to a first surface of a dielectric film. One or more vias are provided through a second surface of the dielectric film by any suitable method, and the vias and portions of the second surface of the dielectric film metallized to provide serial connections between the at least two photovoltaic cells. The metallization may be accomplished by use of one or more photolithography techniques, for example.

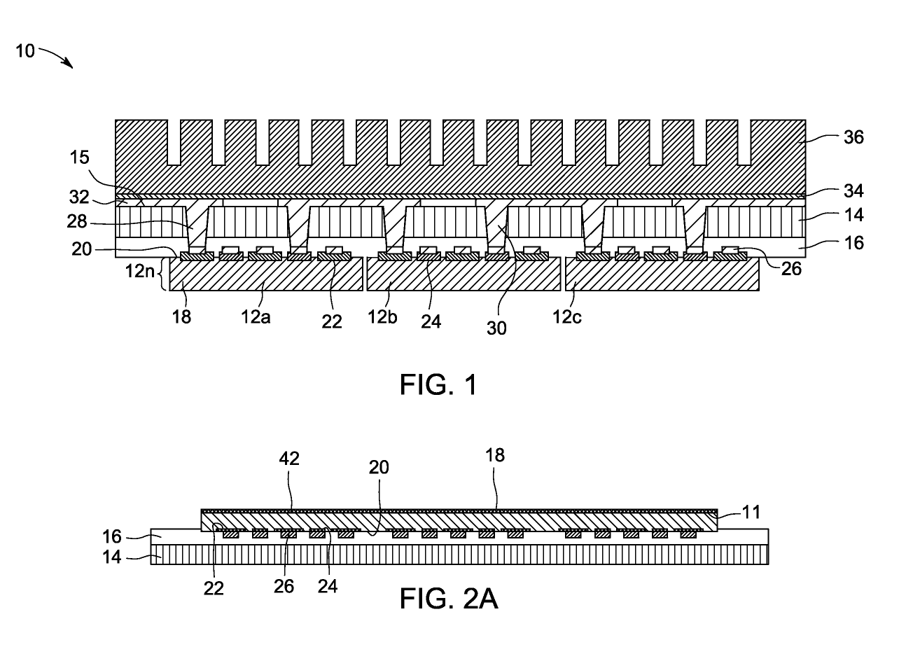

FIG. 1 depicts a sectional side view of a photovoltaic module 10 that includes multiple photovoltaic cells 12n secured to a dielectric film 14 with an adhesive 16. FIG. 1 depicts three photovoltaic cells 12a, 12b, 12c; however, it is to be understood that an array of photovoltaic cells 12n may be formed into a 3×3 square array, 4×4 array, 5×5 array etc., or into a 1×3, 1×4, 1×5, 2×3, 2×4, 2×5, etc. rectangular array.

The substrate used in forming photovoltaic cells 12n may be fabricated out of crystalline silicon, such as a mono-crystalline material or a multi-crystalline material. In one embodiment, the substrate is formed out of a silicon material having a thickness between about 50 μm and about 150 μm. The substrate material may also include one or more dopants, such as a p-type or an n-type depending, in part, on the electrical requirements for the photovoltaic cell. Generally, a mono-crystalline substrate includes a large, single crystal that may include more than one crystal, as long as each crystal is sufficiently sized so electrons and holes do not experience any grain boundaries within the layer. A multi-crystalline material generally has large grains, the width of each grain typically being larger than the thickness of the substrate. Those skilled in the art are familiar with the details regarding all of these types of silicon substrates. Other suitable materials for fabricating the photovoltaic cells 12n include amorphous silicon, single crystal and amorphous silicon hybrid, cadmium telluride, gallium arsenide and copper indium gallium selenium (CIGS) thin film devices. The substrate material may have a thickness of about 1 micron to about 600 microns. The front surface of the substrate material may optionally be textured to enhance light trapping.

Dielectric film 14 may comprise any suitable material and many are known to those of ordinary skill in the art. Suitable dielectric films will have sufficient rigidity to support the photovoltaic cells desirably secured thereto while having sufficient flexibility to allow slight bending of the photovoltaic cells. Exemplary dielectric films include, but are not limited to KAPTON®, APICAL®, UPILEX®, ULTEM®, liquid crystal polymer and polysulfone films. Dielectric film may also include polymer films spin coated onto the photovoltaic array and subsequently cured. Suitable spin coated films include liquid polyimide and polybenzoxazole materials, CYCLOTENE®, and epoxy-based dielectric materials. In some embodiments, a polyimide film, such as, e.g., a KAPTON® polyimide may be used as dielectric film 14. Dielectric film 14 may also comprise combinations of materials, such as, e.g., a layer of polyimide, and a layer of a polyetherimide, such as a ULTEM® polyetherimide.

Dielectric film 14 may be of any suitable thickness, and the thickness may be substantially uniform, if desired. Suitable thicknesses will depend on the material desirably used as the dielectric film. For some materials, dielectric film 14 may be sufficiently rigid if provided in thicknesses as thin as about 5 microns, 10 microns, 15 microns, 20 microns, 25 microns, or greater. Dielectric film 14 will desirably also be thin enough so that it may be useful in the desired application. Although this will also depend upon the particular material chosen and the desired application, dielectric film 14 is expected to have thickness in the range of 10 to 25 μm.

The adhesive 16 may be formed of any suitable material capable of adhering a dielectric material to a substrate, such as the substrate from which photovoltaic cells 12n are fabricated. Such adhesive 16 will allow void-free attach onto the flex film 14 and be subsequently processable for via formation and metallization to the photovoltaic cells 12n. It is also desirable that the adhesive 16 be uniformly applied in a thin layer, to provide a final cured thickness of between 5 μm and 20 μm. Film adhesives useful for this application include SHIN-ETSU® E33, ADFLEMA® manufactured by Namics, and THREEBOND® film materials. A spin coatable adhesive useful for this application includes an epoxy based material recently filed from assignee's docket 234938-1. Adhesive layer 16 may be of any thickness useful to adhere the desired photovoltaic cells 12n to the desired dielectric layer 14, and such thickness may depend upon the particular material chosen for use as the adhesive.

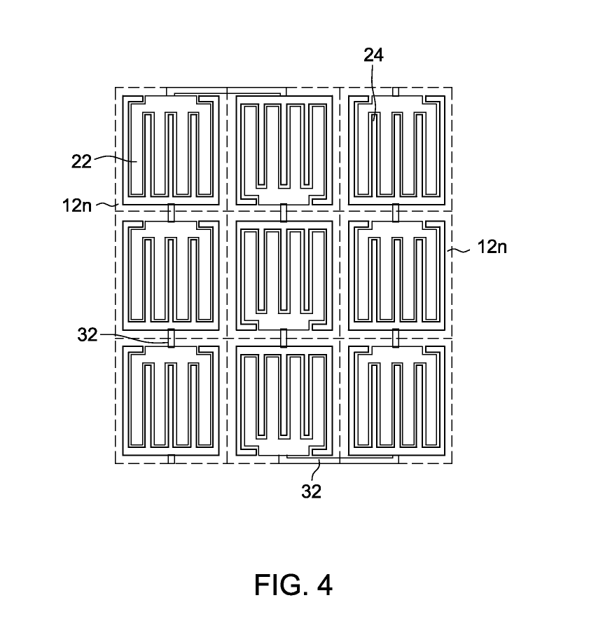

Each of the photovoltaic cells 12n has a sun side (the side intended to collect electromagnetic radiation) 18 opposite a backside 20. The backside 20 has interdigitated fingers 22, 24 doped thereon. Specifically, fingers 22 are formed with a positive doping material, such as, for example, boron, while fingers 24 are formed with a negative doping material, such as, for example, phosphorous. It is to be understood that instead fingers 22 may be formed with a negative doping material and fingers 24 may be formed with a positive doping material. The important aspect is that the doping materials used to form fingers 22, 24 are interdigitated. While FIGS. 3-5 depict fingers 22 and 24, it should be understood that other configurations of doped regions may be formed as long as they are interdigitated.

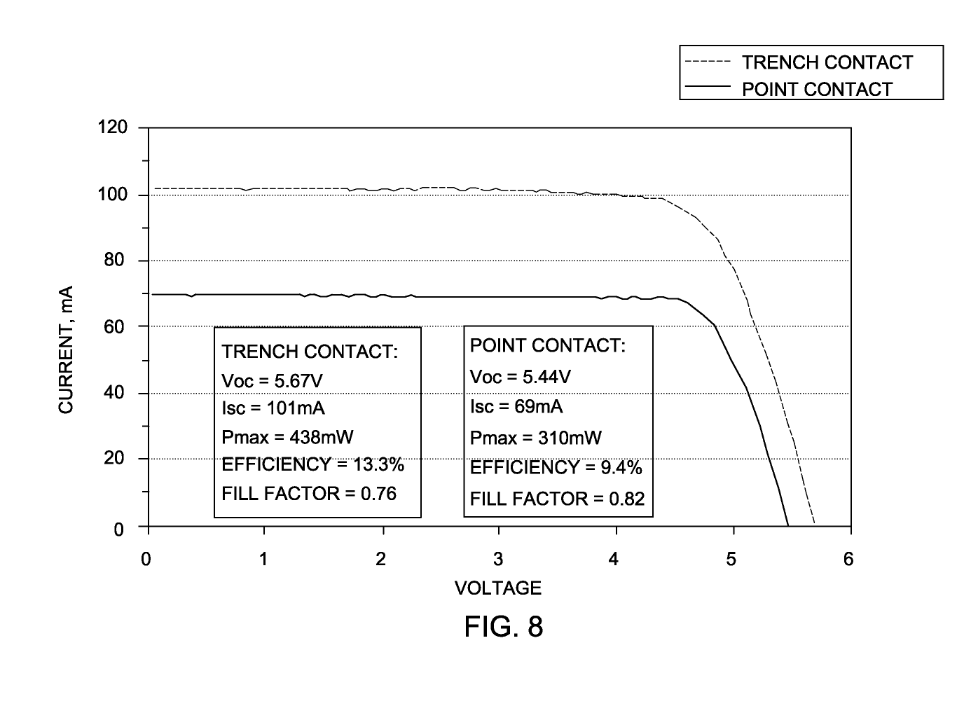

The fingers 22, 24 have electrical contacts 26 formed thereon. The electrical contacts 26 may be trench contacts 26a as shown in FIG. 6 or point contacts 26b as shown in FIG. 7. FIG. 8 depicts the voltage of trench contacts and point contacts against current. As shown, the open circuit voltage (Voc) of trench and point contacts is similar, 5.67 V to 5.44 V.

The backside 20 is adhered by the adhesive 16 to the dielectric film 14. A plurality of vias 28 is formed through the adhesive 16 and the dielectric film 14. As shown in FIG. 1, the vias 28 are filled with a metallized material 30, such as, for example, aluminum (Al), silver (Ag), or copper (Cu). The vias 28 are positioned to allow contact between the metallized material 30 and the electrical contacts 26. A metallization layer 32 is formed on a backside 15 of the dielectric film 14.

A second adhesive 34 is laid over the metallization layer 32 to secure a heat sink 36 to the rest of the photovoltaic module 10. In one embodiment, the heat sink is slightly curved. With the substrate of the array attached to the dielectric film 14 and diced into individual photovoltaic cells, the substrate and dielectric film 14 could be slightly bent to accommodate that slight curve to the heat sink 36. The angle of curvature across one photovoltaic cell from one edge to an opposite edge would generally not exceed 10 degrees, and more typically would be 5 degrees or less. Such a curved device may be used in a solar concentrator system, for example. Such a curved surface may take any shape, but typically may take a parabolic shape.

The vias 28 are desirably spaced so that metallization of the same results in contact of the metallization layer 32 with an electrical contact 26 on a photovoltaic cell 12n. In some embodiments, vias 28 may be accurately placed by alignment with fiducials provided on the photovoltaic cell substrate, e.g., via a vision system such as a machine vision recognition system. In such embodiments, the dielectric film 14, as well as the adhesive 16 used to secure the photovoltaic cell 12n to the dielectric film, is desirably substantially optically transparent so that the fiducials may be seen through the film to assist in the formation of the vias 28. The fiducials themselves may be provided on the substrate in the form of crosshairs formed in the metallization layer on the photovoltaic cells 12n patterned and etched during their fabrication.

The vias 28 may be formed by any one of a number of techniques, including etching (e.g., wet chemical etching or plasma etching), mechanical abrasion, drilling using lasers or ultrasonic techniques. Laser ablation is a fast process meeting the overall targets of solar cell processing and may be preferential in many applications. For instance, a Q-switched Nd:YAG laser beam may be used to form the vias 28.

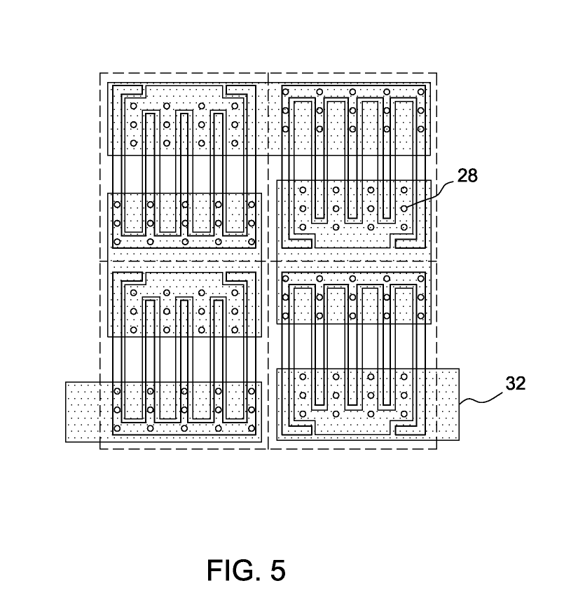

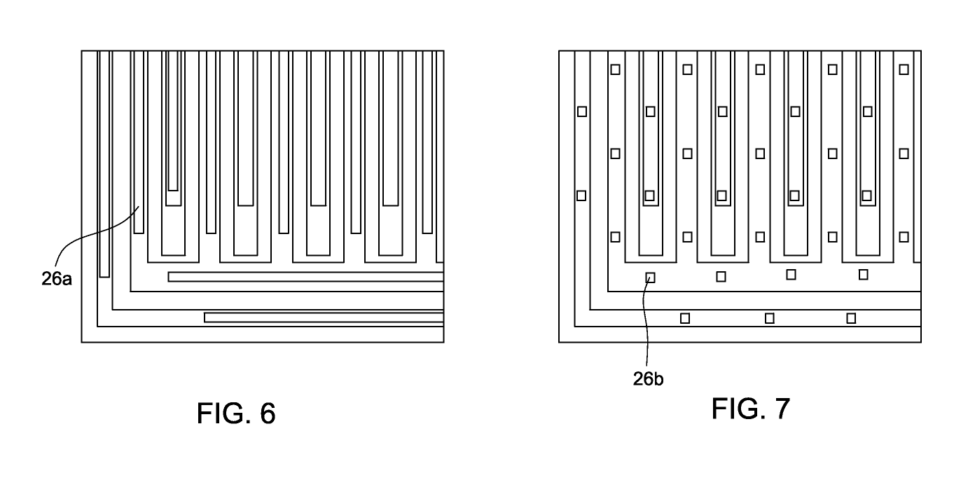

Once the vias 28 are formed, a metallized material 30 is applied to the vias 28 and a metallization layer 32 is applied and patterned on selected portions of the backside 15 of the dielectric film 14. The metallized material 30 and metallization layer 32 may be formed of the same materials, such as, for example, a first layer of titanium followed by a second layer of copper. The metallization layer 32 is patterned to serially connect photovoltaic cells 12n (FIG. 4). Additionally, metallization layer 32 may be patterned to serially connect the individual photovoltaic cells 12n, assist with current flow across portions of the interdigitated fingers 22, 24, and serve as a heat spreading layer from the photovoltaic cells 12n as shown in FIG. 5. The metallization layer 32 may be applied through electroless deposition, and can then be patterned by conventional techniques to form selected portions to serially connect photovoltaic cells 12n.

The metallization layer 32 is required to be both electrically conductive as well as thermally conductive. The second adhesive 34 is required to be electrically insulating to prevent the heat sink 36 acting as an electrical short to the photovoltaic module 10. The second adhesive 34 also should be thermally conductive to form a thermal path from the sun side 18 of the photovoltaic cells 12n, through the interdigitated fingers 22, 24 and through the metallized material 30 and the metallization layer 32 to the heat sink 36. Such adhesives are well known and may consist of a metal oxide (alumina) or metal nitride (boron nitride) filled epoxy material. In this way, an embodiment of the invention combines electrically and thermally conductive functionality into a single set of materials.

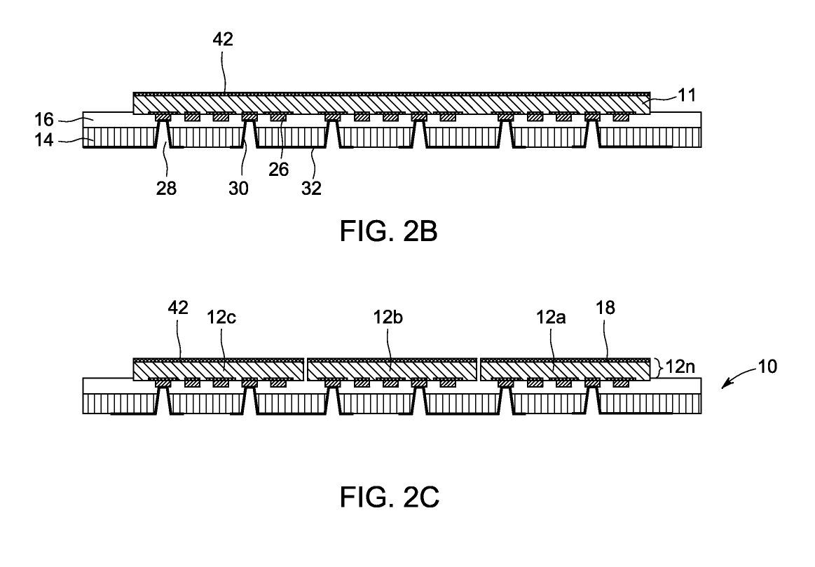

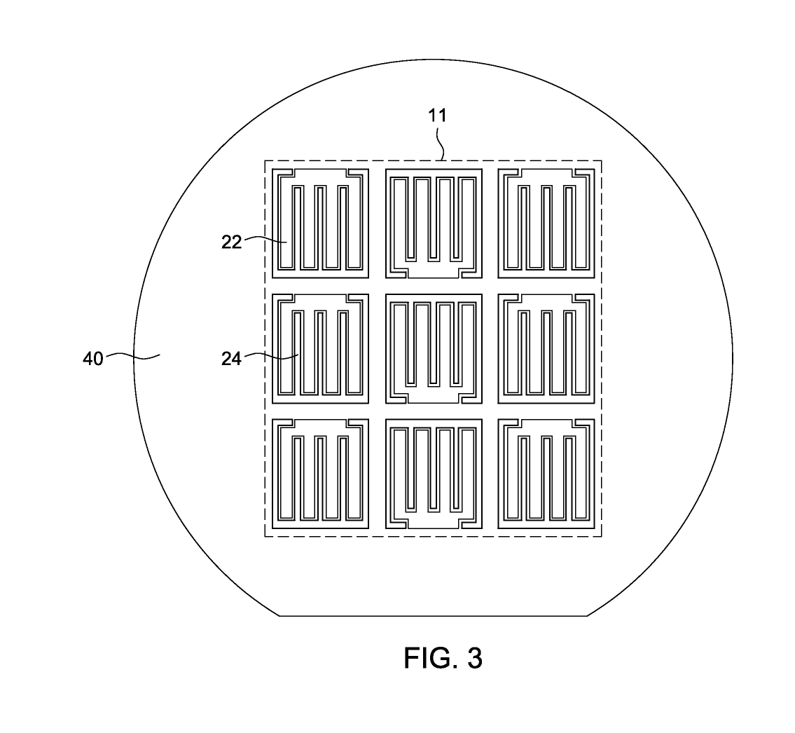

FIGS. 2A-2C and 3 depict a photovoltaic module 10 in varying stages of a fabrication sequence according to one embodiment. As shown in FIG. 3, a photovoltaic cell array 11, with its silicon fabrication portion completed, includes interdigitated fingers 22, 24 formulated on a wafer 40. Electrical contacts 26 are positioned on the fingers 22, 24. The array 11 is then removed, i.e., cut out, from the wafer 40, preferably as a single piece.

The array 11 is then adhered to the dielectric film 14 through an adhesive material 16 (FIG. 2(a)). Specifically, the backside 20 of the array 11 is adhered to the dielectric film 14 by way of the adhesive 16. In this way, the back side of the array 11, which has a heavily phosphorous doped region 42 becomes the sun side 18 of the photovoltaic module 10.

Fiducial marks (not shown) may be located on a front side of the array 11, i.e., the side facing the dielectric film 14. Based upon the location of the fiducial marks, which can be seen through the adhesive 16 and the dielectric film 14, vias 28 are then formed through the dielectric film 14 and the adhesive 16 to the electrical contacts 26. Metallized material 30 is then put in the vias 28. The metallized material 30 may line the walls of the vias 28 (as shown in FIGS. 2B and 2C) or may completely fill the vias 28 (as shown in FIG. 1). Then, a metallization material 32 is laid in a pattern on a backside of the dielectric film 14.

The substrate forming the array 11 is of a material that is electrically conductive. As such, the array 11 would act as an electrical short to the photovoltaic module 10 if it remained a whole array 11. Thus, as shown in FIG. 2C, the array 11 is separated into an array of photovoltaic cells 12n. This may be done by aligning to an edge of the array 11, indexing over and sawing at predetermined locations to a specific depth (typically the thickness of the silicon portion only of the photovoltaic module) to separate the cells 12n. In this way, an array of photovoltaic cells may be aligned and positioned on a dielectric film with a minimal spacing therebetween. For example, a commonly used saw blade for cutting silicon material may have a thickness of between about 50 μm and about 10 μm, thus creating that spacing between two adjacent photovoltaic cells.

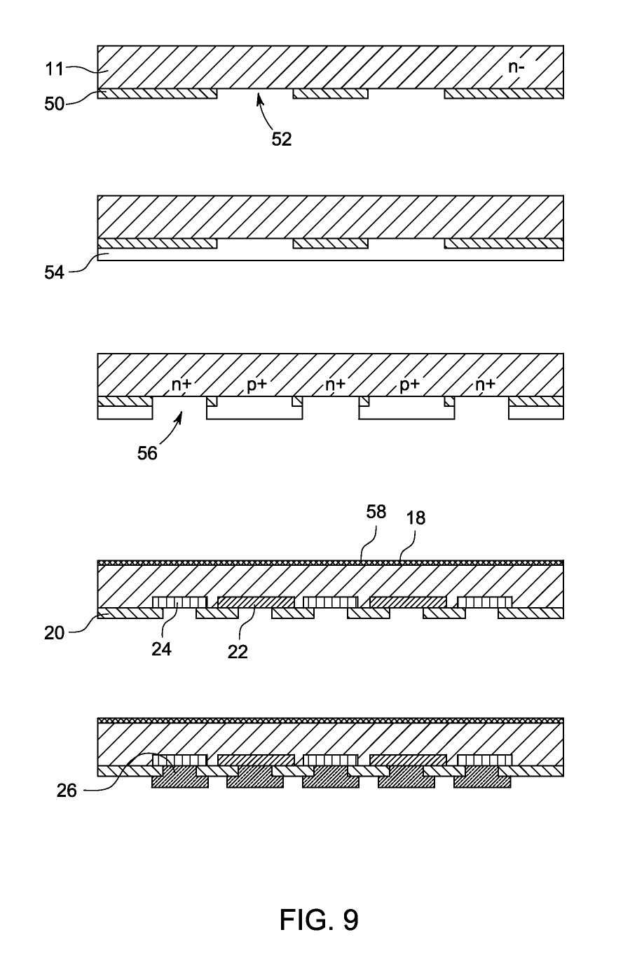

FIG. 9 illustrates in greater detail the preparation of the array 11. As shown, a layer of thermal oxide is patterned and open areas 52 are etched. A layer of borosilicate glass (BSG) 54 is deposited on the thermal oxide and over the etched open regions. The layer of BSG 54 is used as a p+ diffusion source of boron atoms. Open areas 56 are formed through the BSG layer and the thermal oxide layer. These open areas 56 are formed for subsequent doping with phosphorous atoms to form n+ regions. The doping of phosphorous atoms may be accomplished through a vapor deposition of POCl₃.

After the POCl₃ doping and the boron diffusion, n+ and p+ junctions (the interdigitated fingers 22, 24) are formed on the backside 20 of the array 11. Then, a passivation glass is deposited and contact areas to the junctions are etched into the passivation glass. Further, a metallization layer such as aluminum is applied over etched contact areas and subsequently patterned to form electrical contacts 26. Finally, the sun side 18 of the array 11 has a silicon nitride anti-reflection layer 58 added.

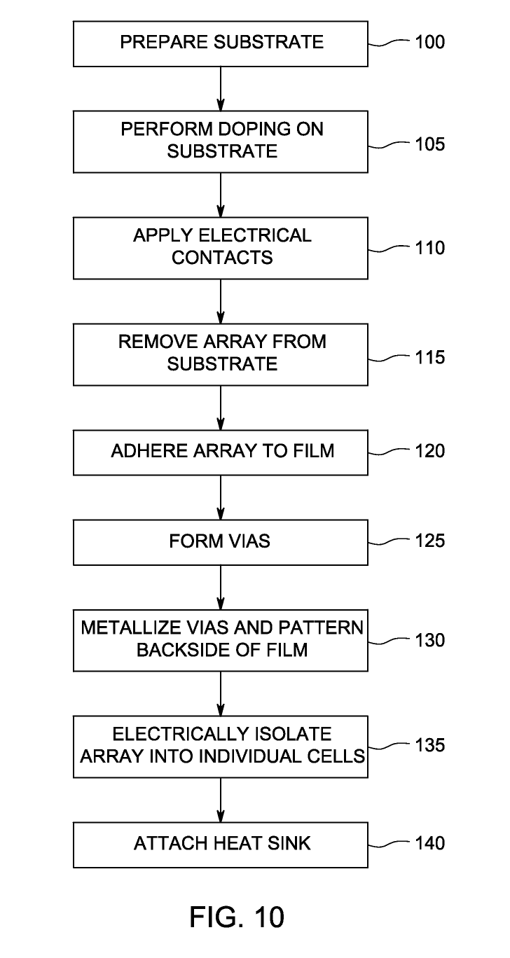

FIG. 10 depicts process steps for forming a photovoltaic module, such as photovoltaic module 10, in accordance with an embodiment of the invention. At step 100, a substrate is prepared. The substrate may be, for example, a crystalline silicon material formed in a wafer 40 (FIG. 3). Preparation in this step 100 may include thermal oxidation to prevent deposition of doping materials onto the silicon substrate in selected areas. Preparation in this step 100 also may include scribing fiducial marks on the substrate.

At step 105, the substrate is doped. Doping of the substrate may include doping one side of the substrate with a phosphorous dopant. Doping of the substrate also may include patterning interdigitated doped regions on another side of the substrate. For example, fingers of negative dopant material and positive dopant material, such as fingers 22 and 24, may be patterned and applied to a side of the substrate. At step 110, electrical contacts are applied to the interdigitated doped regions. The electrical contacts may be trench contacts, point contacts, or a combination of both types of contacts. The interdigitated doping and application of electrical contacts are such as to create an array of photovoltaic cells, such as array 11 of photovoltaic cells 12n.

The array is removed from the substrate at step 115. This may be accomplished by cutting excess portions of the substrate from the array. It should be understood that steps 105 and 110 may take place either before or after step 115.

Next, at step 120, the array 11 is adhered to a dielectric film, such as dielectric film 14. The array 11 is adhered to the film 14 through an adhesive layer, such as adhesive 16. Specifically, the side of the array 11 having the interdigitated fingers and the electrical contacts is the side adhered to the dielectric film 14. Then, the entire assembly is cured in place.

Once the array 11 is adhered to the film 14, vias are formed through the film and the adhesive to the electrical contacts at step 125. The vias, such as vias 28, may be formed by laser ablation of the dielectric and adhesive materials in specific areas based upon fiducial marks located on the array 11 and visible through the adhesive and film layers.

At step 130, the vias are metallized. The vias are metallized by either lining the vias with an electrically and thermally conductive material or filling the vias with such a material, such as metallized material 30. Further, a backside of the film 14 is patterned and metallized with, for example, metallization layer 32. Metallized material 30 and metallization layer 32 may be formed of the same material. More particularly, the patterned metallization layer 32 is such as to electrically connect interdigitated fingers 22 (doped with a boron dopant, for example) of one photovoltaic cell in the module with interdigitated fingers 24 (doped with a phosphorous dopant, for example) of a second photovoltaic cell in the module.

Since the substrate of the array as a whole would act as an electrical short for the photovoltaic module, at step 135 the array 11 is separated into individual photovoltaic cells, thereby electrically isolating them from each other. This step may be accomplished by any technique capable of doing so, and, for example, may be expediently carried out using a wafer saw. The saw may be aligned using HDI placed fiducials or the edges of the array 11 as reference markers.

At step 140, a heat sink is adhered to the photovoltaic module 10. The adhesive used is one that is both electrically isolating and thermally conducting. By using such an adhesive, a thermal path from the sun side 18 of the photovoltaic cells 12n to a heat sink, such as heat sink 36, is completed. Thus, heat is allowed to migrate through the photovoltaic cells 12n, through the electrical contacts 26 and into the metallized material 30 and metallization layer 32, and through the adhesive layer 34 to the heat sink 36.

The photovoltaic module 12 thus formed allows for the adjustment of the voltage of individual cells within the module. Specifically, the ability to form interconnections on the backside of the module 12 allows series connection of active regions of the cells. The ability to adjust the voltage of individual cells within a module can be useful in forming a higher voltage solar cell, for example. Solar cells that operate at a higher voltage can be arranged in a series/parallel fashion. Such an arrangement reduces loss of power due to shadowing effects that are common in series string module architectures.

While the invention has been described in detail in connection with only a limited number of embodiments, it should be readily understood that the invention is not limited to such disclosed embodiments. Rather, the invention can be modified to incorporate any number of variations, alterations, substitutions or equivalent arrangements not heretofore described, but which are commensurate with the spirit and scope of the invention. For example, while embodiments have been described in terms that may initially connote singularity, it should be appreciated that multiple components may be utilized. Additionally, while various embodiments of the invention have been described, it is to be understood that aspects of the invention may include only some of the described embodiments. Accordingly, the invention is not to be seen as limited by the foregoing description, but is only limited by the scope of the appended claims.

What is claimed as new and desired to be protected by Letters Patent of the United States is:

1. A photovoltaic module, comprising:
an array of photovoltaic cells, each said photovoltaic cell comprising:
a substrate material having a sun side and a backside;
a first plurality of doped regions interdigitated with a second plurality of doped regions, both said doped regions located on the backside, wherein one of the plurality of doped regions is positively doped and the other plurality of doped regions is negatively doped;
electrical contacts on each of the first and second plurality of doped regions;
a dielectric material adhered to the backside of the substrate material, wherein vias are formed through said dielectric material and extending to at least a portion of said electrical contacts; and
metallized material extending from said at least a portion of said electrical contacts through said vias and being patterned on a backside of the dielectric material, said metallized material being formed of a material that is both electrically and thermally conductive.

2. The photovoltaic module of claim 1, further comprising a heat sink adhered through an adhesive layer to the backside of the dielectric material, said adhesive layer being formed of a material that is electrically insulating and thermally conductive.

3. The photovoltaic module of claim 2, wherein said heat sink has a curved surface to which the photovoltaic device is adhered

4. The photovoltaic module of claim 3, wherein said curved surface is parabolic shaped with an angle of curvature not exceeding 10 degrees across opposing edges of any single photovoltaic cell in the array.

5. A photovoltaic module of claim 1, wherein spacing between adjacent cells of the array is in a range between about 50 μm and 10 μm.

6. The photovoltaic module of claim 2, wherein a thermal path is formed from the sun side of the substrate to the electrical contacts, through the metallized material to the heat sink.

7. The photovoltaic module of claim 1, wherein the first and second plurality of doped regions are formed as interdigitated fingers.

8. The photovoltaic module of claim 1, wherein the first plurality of doped regions are electrically connected to the second plurality of doped regions through the electrical contacts and the metallized material.

9. The photovoltaic module of claim 1, wherein the first plurality of doped regions is doped with a boron dopant and the second plurality of doped regions is doped with a phosphorous dopant.

10. The photovoltaic module of claim 1, wherein the first plurality of doped regions is doped with a phosphorous dopant and the second plurality of doped regions is doped with a boron dopant.

11. The photovoltaic module of claim 1, wherein the dielectric material is a polyimide film.

12. The photovoltaic module of claim 1, wherein the dielectric material is a polyetherimide film.

13. The photovoltaic module of claim 1, wherein voltage of at least one of the photovoltaic cells is adjustable.

14. A method for fabricating a photovoltaic module comprising:
securing a backside contact photovoltaic cell array as an integral piece onto a first side of a dielectric material;
forming at least two vias through the dielectric material to each cell of the photovoltaic cell array;
patterning a metal layer on selected portions of a second side of the dielectric material and in the vias so that individual photovoltaic cells of the photovoltaic cell array are serially connected together, said metal layer also creating a thermal pathway; and
cutting the integral piece into separate photovoltaic cells, thereby electrically isolating the photovoltaic cells.

15. The method of claim 14, further comprising preparing positively doped and negatively doped regions on the integral piece prior to said securing step.

16. The method of claim 15, wherein said preparing comprises:
depositing a layer of thermal oxide on a surface of the integral piece;
etching open regions in the layer of thermal oxide;
depositing a layer of borosilicate glass (BSG) on the layer of thermal oxide and over the etched open regions, the BSG acting as a p+ diffusion source of boron atoms to form p+ regions;
forming open areas through the BSG and the thermal oxide layer;
doping the surface of the integral piece at the open areas to form n+ regions;
depositing a passivation glass over the surface of the integral piece; and
etching in areas of the passivation glass.

17. The method of claim 16, wherein said doping the surface of the integral piece is accomplished through a vapor deposition of POCl₃.

18. The method of claim 16, further comprising adding a silicon nitride anti-reflection layer to a second surface of the integral piece.

19. The method of claim 16, wherein said patterning comprises patterning electrical contacts in the etched in areas of the passivation glass.

20. The method of claim 14, further comprising adhering a heat sink through an adhesive layer to a backside of the dielectric material.

21. The method of claim 20, wherein said adhesive layer is formed of a material that is electrically insulating and thermally conductive.

22. The method of claim 14, wherein said forming at least two vias is accomplished through wet chemical etching, plasma etching, mechanical abrasion, laser drilling, ultrasonic techniques, or laser ablation.

23. The method of claim 14, wherein said patterning includes filling the vias with the metal layer.

24. The method of claim 14, wherein said patterning includes lining the vias with the metal layer.

25. The method of claim 14, wherein voltage of at least one of the photovoltaic cells is adjustable.
